(19) United States
(12) Patent Application Publication
(10) Pub. No.: US 2026/0147016 A1
(43) Pub. Date: May 28, 2026

(54) PROBE PIN AND SOCKET

(71) Applicant: OMRON Corporation, Kyoto-shi (JP)

(72) Inventors: Yuya YAMASHITA, Kyoto-shi (JP); Shunsuke TAKAGI, Kyoto-shi (JP); Naoya SASANO, Kyoto-shi (JP); Takahiro SAKAI, Kyoto-shi (JP)

(21) Appl. No.: 19/379,834

(22) Filed: Nov. 5, 2025

(30) Foreign Application Priority Data
Nov. 28, 2024 (JP) 2024-207529

(51) Int. Cl. G01R 1/067; G01R 1/04

(52) U.S. Cl. CPC G01R 1/06716; G01R 1/0466

(57) ABSTRACT

A probe pin includes a first elastic portion configured to be elastically deformed in a first direction, a first contact portion, and a second contact portion. The first contact portion includes a second elastic portion configured to be elastically deformed in a second direction and is connected to a first end of the first elastic portion in the first direction. The second contact portion is connected to a second end located on an opposite side of the first end, of the first elastic portion in the first direction. The first contact portion includes a first contact point located at a position of the second elastic portion that the first contact point is superposed on the first elastic portion, the first contact point being configured to be in contact along the second direction. The second contact portion includes a second contact point configured to be in contact along the first direction.

### CROSS REFERENCE TO RELATED APPLICATIONS

The present invention claims priority under 35 U.S.C. § 119 to Japanese Application No. 2024-207529, filed Nov. 28, 2024, the entire contents of which being incorporated herein by reference.

### TECHNICAL FIELD

The present disclosure relates to a probe pin and a socket.

### BACKGROUND ART

Patent Literature 1 discloses a probe pin. The probe pin of Patent Literature 1 includes an elastic portion provided with a through hole, a first contact portion positioned at one end of the elastic portion in a longitudinal direction of the elastic portion, and a second contact portion positioned at the other end of the elastic portion in the longitudinal direction of the elastic portion.

### CITATION LIST

### Patent Literature

Patent Literature 1: JP 2017-223628 A

### SUMMARY OF INVENTION

### Technical Problem

In the probe pin of Patent Literature 1, since the contact portions are provided at both ends of the elastic portion in the longitudinal direction of the elastic portion, it can be difficult to use the probe pin for an inspection object that needs to be in contact from a direction intersecting the longitudinal direction of the elastic portion.

An object of the present disclosure is to provide a probe pin contactable from a second direction intersecting a first direction in which a first elastic portion is elastically deformed, and a socket including the probe pin.

### Solution To Problem

A probe pin according to an aspect of the present disclosure includes:
a first elastic portion configured to be elastically deformed in a first direction;
a first contact portion including a second elastic portion configured to be elastically deformed in a second direction intersecting the first direction, the first contact portion being connected to a first end of the first elastic portion in the first direction; and
a second contact portion connected to a second end of the first elastic portion in the first direction, the second end being located on an opposite side of the first end, wherein
the first contact portion includes a first contact point located at a position of the second elastic portion that the first contact point is superposed on the first elastic portion when viewed along the first direction, the first contact point being configured to be in contact along the second direction, and
the second contact portion includes a second contact point configured to be in contact along the first direction.

A socket according to an aspect of the present disclosure includes:
the probe pin according to the aspect; and
a housing including an accommodating portion that accommodates the probe pin, wherein
the first contact point is located outside the accommodating portion.

### Advantageous Effects Of Invention

According to the present disclosure, it is possible to realize the probe pin contactable from a second direction intersecting a first direction in which the first elastic portion is elastically deformed, and the socket including the probe pin.

### BRIEF DESCRIPTION OF DRAWINGS

FIG. 1 is a perspective view illustrating a socket according to one aspect of the present disclosure.

FIG. 2 is a cross-sectional view taken along line II-II of FIG. 1.

FIG. 3 is a plan view illustrating a probe pin according to one aspect of the present disclosure.

FIG. 4 is a plan view illustrating a first modification of the probe pin of FIG. 3.

FIG. 5 is a plan view illustrating a second modification of the probe pin of FIG. 3.

FIG. 6 is a plan view illustrating a third modification of the probe pin of FIG. 3.

FIG. 7 is a plan view illustrating a fourth modification of the probe pin of FIG. 3.

FIG. 8 is a plan view illustrating a fifth modification of the probe pin of FIG. 3.

FIG. 9 is a plan view illustrating a sixth modification of the probe pin of FIG. 3.

### DESCRIPTION OF EMBODIMENTS

Hereinafter, an example of the present disclosure will be described with reference to the accompanying drawings. The following description is merely exemplary in nature and does not limit the present disclosure, the applied object of the present disclosure, and the application of the present disclosure. The accompanying drawings are schematic drawings, and the illustrated configuration and the product may have different dimensional ratios and the like. In the following description, terms such as “about” or “substantially” mean that the value, shape, or the like following these terms includes a range of acceptable error as determined by those skilled in the art.

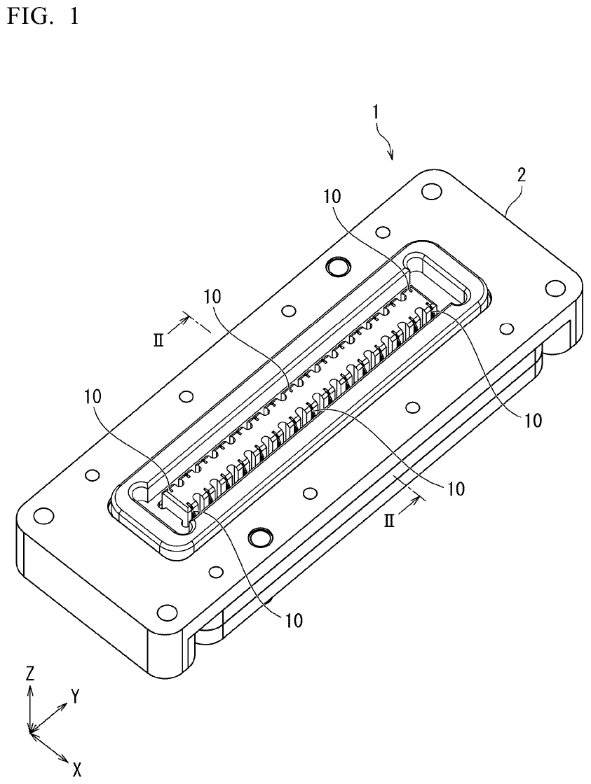

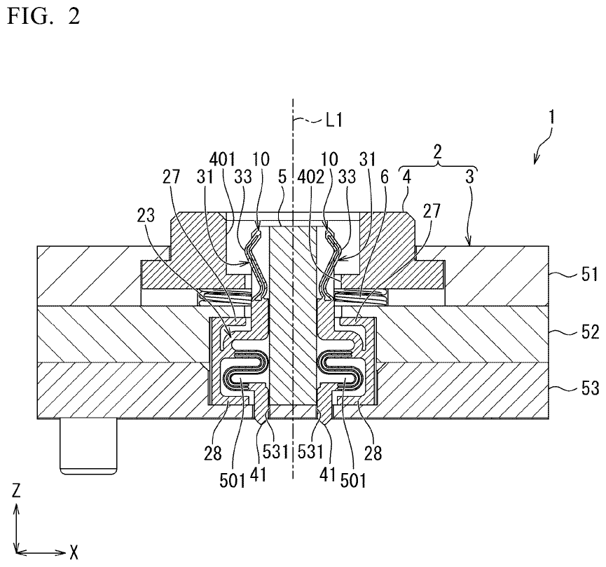

As illustrated in FIG. 1 and FIG. 2, a probe pin 10 of one embodiment of the present disclosure constitutes a part of a socket 1. As an example, the socket 1 includes a plurality of pairs of probe pins 10 and a housing 2 that accommodates the plurality of pairs of probe pins 10 in a mutually electrically independent state.

As illustrated in FIG. 2, the pair of probe pins 10 is located symmetrically with respect to an imaginary straight line L1 extending in a first direction (for example, in the Z direction) when viewed along the plate thickness direction (for example, in the Y direction) of the probe pin 10. As illustrated in FIG. 1, the plurality of pairs of probe pins 10 are accommodated in the housing 2 in a state of being arranged at intervals in a plate thickness direction Y.

As illustrated in FIG. 1 and FIG. 2, the housing 2 has, as an example, an insulating substantially rectangular parallelepiped shape, and includes a main body portion 3, a connecting portion 4 provided in a movable state in the first direction Z with respect to the main body portion 3, and a core portion 5. The core portion 5 includes a plurality of accommodating portions 501 for accommodating the probe pins 10.

As illustrated in FIG. 2, the main body portion 3 includes three members 51, 52, and 53 stacked in the first direction Z. The connecting portion 4 is provided on the member 51 located at one end in the first direction Z. The core portion 5 is located at a center of the main body portion 3 in the second direction (for example, in the X direction) intersecting the first direction Z. The core portion 5 is held by two members 52 and 53. The member 53 includes an opening 531 in which the second contact point 41 of each probe pin 10 is accommodated.

A plurality of springs 6 are accommodated in the main body portion 3. The plurality of springs 6 are located between the connecting portion 4 and the member 52, and bias the connecting portion 4 in the first direction Z and in a direction away from the member 52.

The connecting portion 4 includes a recess 401. The recess 401 includes an opening 402 provided at a bottom of the recess 401 and configured to accommodate a part of the core portion 5. A part of the core portion 5 is located inside the recess 401 through the opening 402. A first contact point 33 of each probe pin 10 is located outside the accommodating portion 501 inside the recess 401.

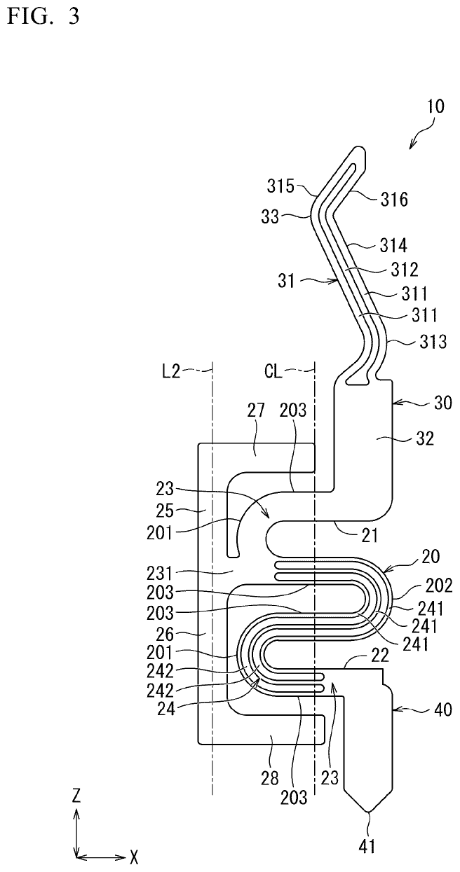

Each probe pin 10 has, for example, an elongated thin plate shape formed by electroforming using a conductive material, and includes a first elastic portion 20, a first contact portion 30, and a second contact portion 40 as illustrated in FIG. 3.

The first elastic portion 20 is configured to be elastically deformed in the first direction Z. The first contact portion 30 is connected to one end (hereinafter, it is referred to as a first end 21) of the first elastic portion 20 in the first direction Z. The second contact portion 40 is connected to the other end (hereinafter, it is referred to as a second end 22) of the first elastic portion 20 in the first direction Z, the second end 22 being located on the opposite side of the first end 21.

In this aspect, the first elastic portion 20 includes two first curved portions 201, one second curved portion 202, and four connecting portions 203. The first curved portion 201 and the second curved portion 202 are alternately located in the first direction Z. The two first curved portions 201 are spaced apart in the first direction Z. The second curved portion 202 is located between the two first curved portions 201 in the first direction Z. The first curved portion 201 and the second curved portion 202 adjacent in the first direction Z are connected by the connecting portion 203.

The first curved portion 201 is located in a region on one side with respect to a center line CL passing through the center of the first elastic portion 20 in the second direction X and extending in the first direction Z, and protrudes in a direction away from the center line CL in the second direction X. One of the two first curved portions 201 is connected to the first contact portion 30 via the connecting portion 203, and the other of the two first curved portions 201 is connected to the second contact portion 40 via the connecting portion 203. As an example, a middle between a portion of the first curved portion 201 farthest away from the second curved portion 202 in the second direction X and a portion of the second curved portion 202 farthest away from the first curved portion 201 in the second direction X is defined as the “center of the first elastic portion 20 in the second direction X”.

The second curved portion 202 is located in a region opposite to the first curved portion 201 with respect to the center line CL of the elastic portion 20, and protrudes in a direction opposite to the first curved portion 201 in the second direction X. Both ends of the second curved portion 202 are connected to the first curved portion 201 via the connecting portion 203.

The connecting portion 203 is located between the first curved portion 201 and the second curved portion 202 in the second direction X and extends along the second direction X.

In this aspect, the first elastic portion 20 includes a first portion 23 and a second portion 24. The first portion 23 is configured by a single member, and the second portion 24 is configured by a plurality of members. As an example, the first curved portion 201 and the connecting portion 203 located closest to the first contact portion 30, and the portion constituting the second end 22 of the connecting portion 203 located closest to the second contact portion 40 constitute the first portion 23. A portion other than the first portion 23 of the first elastic portion 20 constitutes the second portion 24. As an example, the second portion 24 is configured by three elastic pieces 241. The three elastic pieces 241 are located with a gap 242 therebetween in a width direction intersecting an extending direction (for example, a direction along a shape of the first elastic portion 20) in which the first elastic portion 20 extends.

In this aspect, the first elastic portion 20 includes a first support portion 25 and a second support portion 26. The first support portion 25 extends from the first portion 23 in the first direction Z and in a direction approaching the first contact portion 30. The second support portion 26 extends from the first portion 23 in the first direction Z and in a direction approaching the second contact portion 40. As an example, the first portion 23 includes an auxiliary portion 231 extending in the second direction X and in a direction away from the center line CL from a portion where the first curved portion 201 of the first portion 23 and the connecting portion 203 of the second portion 24 are connected. The first support portion 25 and the second support portion 26 extend from the auxiliary portion 231 and are located on an imaginary straight line L2 substantially parallel to the center line CL. A gap is provided between the first support portion 25 and the second support portion 26 and the first curved portion 201 in the second direction X.

In this aspect, the first elastic portion 20 includes a first extension portion 27 and a second extension portion 28. The first extension portion 27 extends toward the center line CL along the second direction X from an end closer to the first contact portion 30 among both ends of the first support portion 25 in the first direction Z. When viewed along the first direction Z, a part of the first extension portion 27 is superposed on the first elastic portion 20. The second extension portion 28 extends toward the center line CL along the second direction X from an end closer to the second contact portion 40 among both ends of the second support portion 26 in the first direction Z. When viewed along the first direction Z, a part of the second extension portion 28 overlaps the first elastic portion 20. A gap is provided between the first extension portion 27 and the first contact portion 30 in the second direction X, and a gap is provided between the second extension portion 28 and the second contact portion 40 in the second direction X. A gap is provided between the first extension portion 27 and the connecting portion 203 in the first direction Z, and a gap is provided between the second extension portion 28 and the connecting portion 203 in the first direction Z.

As illustrated in FIG. 2, in a state where the probe pin 10 is accommodated in the accommodating portion 501, the first extension portion 27 and the second extension portion 28 are in contact with an inner surface of the housing 2 constituting the accommodating portion 501. The first extension portion 27 is in contact with the member 52, and the second extension portion 28 is in contact with the member 53. As an example, the second extension portion 28 has a length in the second direction X longer than that of the first extension portion 27. As illustrated in FIG. 3, the first extension portion 27 extends from the imaginary straight line L2 to the center line CL, and the second extension portion 28 extends from the imaginary straight line L2 beyond the center line CL to a region where the second curved portion 202 is located.

The first contact portion 30 includes a second elastic portion 31 and a first contact point 33. The second elastic portion 31 is configured to be elastically deformed in the second direction X. The first contact point 33 is located at a position being superposed on the first elastic portion 20 of the second elastic portion 31 when viewed along the first direction Z, and is configured to be in contact with a contact object (for example, a terminal of a connector) along the second direction X.

In this aspect, the first contact portion 30 includes a plate-like portion 32 configured by a single member and the second elastic portion 31, and is located in a region where the second curved portion 202 is located with respect to the center line CL. The plate-like portion 32 has a substantially rectangular shape when viewed along the thickness direction Y, and extends along the first direction Z. The connecting portion 203 of the first portion 23 of the first elastic portion 20 is connected from the second direction X to an end closer to the first elastic portion 20 among both ends of the plate-like portion 32 in the first direction Z. The second elastic portion 31 is connected to an end farther from the first elastic portion 20 among both ends of the plate-like portion 32 in the first direction Z.

As an example, the second elastic portion 31 includes two elastic pieces 311 extending along the first direction Z. A gap 312 is provided between the two elastic pieces 311. The elastic piece 311 includes two curved portions 313 and 315 and two linear portions 314 and 316. The curved portion 313 protrudes from the plate-like portion 32 in the second direction X and in a direction away from the center line CL. The linear portion 314 extends straight from the curved portion 313 in a direction intersecting the center line CL and along the center line CL. The curved portion 315 protrudes in a direction opposite to the curved portion 313 in the second direction X and is located closest to the center line CL in a portion constituting the elastic piece 311. The curved portion 315 of the elastic piece 311 close to the center line CL constitutes the first contact point 33. The linear portion 316 extends straight from the curved portion 313 in a direction intersecting the center line CL and along a direction away from the center line CL. The linear portions 316 of the two elastic pieces 311 are connected to each other at distal ends away from the curved portion 315.

As illustrated in FIG. 2, among the pair of probe pins 10, the probe pin 10 located on one side with respect to the imaginary straight line L1 is defined as a first probe pin 10, and the probe pin 10 located on the opposite side of the first probe pin 10 with respect to the imaginary straight line L1 is defined as a second probe pin 10. The first contact point 33 of the first probe pin 10 is located at an end farther from the second probe pin 10 among both ends of the second elastic portion 31 in the second direction X. The first contact point 33 of the second probe pin 10 is located at an end farther from the first probe pin 10 among both ends of the second elastic portion 31 in the second direction X.

The second contact portion 40 includes the second contact point 41. The second contact point 41 is configured to be in contact with a contact object (for example, an electrode of the substrate) along the first direction Z. In the present aspect, the second contact portion 40 has a substantially rectangular shape when viewed along the thickness direction Y, and extends along the first direction Z. The second contact portion 40 is located in a region where the second curved portion 202 is located with respect to the center line CL, and a part or the whole of the second contact portion 40 is superposed on the first contact portion 30 when viewed along the thickness direction Y.

The connecting portion 203 of the second portion 24 of the first elastic portion 20 is connected from the second direction X to an end closer to the first elastic portion 20 among both ends of the second contact portion 40 in the first direction Z. Among both ends of the second contact portion 40 in the first direction Z, an end farther from the first elastic portion 20 has a shape tapered as separating from the first elastic portion 20 in the first direction Z. The second contact point 41 is located at a distal end of the tapered shape.

The probe pin 10 can exhibit the following effects.

The probe pin 10 includes the first elastic portion 20, the first contact portion 30, and the second contact portion 40. The first elastic portion 20 is configured to be elastically deformed in the first direction Z. The first contact portion 30 includes the second elastic portion 31 configured to be elastically deformed in the second direction X, and is connected to a first end among both ends of the first elastic portion 20 in the first direction Z. The second contact portion 40 is connected to a second end among both ends of the first elastic portion 20 in the first direction Z, the second end being located on the opposite side of the first end. The first contact portion 30 includes the first contact point 33 located at a position of the second elastic portion 31 that the first contact point 33 is superposed on the first elastic portion 20 when viewed along the first direction, the first contact point being configured to be in contact with the first elastic portion 20 along the second direction X. The second contact portion 40 includes the second contact point 41 configured to be in contact along the first direction Z. With such a configuration, it is possible to realize the probe pin 10 contactable from the second direction X intersecting the first direction Z in which the first elastic portion 20 is elastically deformed.

Since the first contact portion 30 includes the second elastic portion 31, the probe pin 10 can suppress a change in a position of the first contact point 33 in the first direction Z when the first contact point 33 contacts the contact object. For example, when the contact object is brought close to and into contact with the socket 1 from the first direction, the first contact point 33 slides with respect to the contact object. Therefore, the contact reliability of the probe pin 10 can be enhanced.

The first elastic portion 20 includes a first portion 23 configured by a single member and a second portion 24 configured by a plurality of members. With such a configuration, it is possible to realize the probe pin 10 contactable from the second direction X intersecting the first direction Z in which the first elastic portion 20 is elastically deformed.

The first elastic portion 20 includes the first support portion 25 extending from the first portion 23 in the first direction Z and in a direction approaching the first contact portion 30. With such a configuration, it is possible to more reliably suppress a change in the position of the first contact point 33 in the first direction Z when the first contact point 33 contacts the contact object.

The first elastic portion 20 includes the second support portion 26 extending from the first portion 23 in the first direction Z and in a direction approaching the second contact portion 40. With such a configuration, it is possible to more reliably suppress a change in the position of the first contact point 33 in the first direction Z when the first contact point 33 contacts the contact object.

The socket 1 can exhibit the following effects.

The socket 1 includes the probe pin 10 and the housing 2 including the accommodating portion 501 that accommodates the probe pin 10. The first contact point 33 is located outside the accommodating portion 501. With such a configuration, it is possible to realize the socket 1 contactable from the second direction X intersecting the first direction Z in which the first elastic portion 20 is elastically deformed.

The first elastic portion 20 includes the first support portion 25 and the first extension portion 27. The first extension portion 27 extends in the second direction X from an end closer to the first contact portion 30 among both ends of the first support portion 25 in the first direction Z and is in contact with the inner surface of the housing 2 constituting the accommodating portion 501. A part of the first extension portion 27 is superposed on the first elastic portion 20 when viewed along the first direction Z. With such a configuration, it is possible to more reliably suppress a change in the position of the first contact point 33 in the first direction Z when the first contact point 33 contacts the contact object.

The first elastic portion 20 includes the second support portion 26 and the second extension portion 28. The second extension portion 28 extends in the second direction X from an end closer to the second contact portion 40 among both ends of the second support portion 26 in the first direction Z. The second extension portion 28 is in contact with the inner surface of the housing 2 facing the inner surface of the housing 2 with which the first extension portion 27 is in contact in the first direction Z among the inner surfaces of the housing 2 constituting the accommodating portion 501. A part of the second extension portion 28 overlaps the first elastic portion 20 when viewed along the first direction Z. With such a configuration, it is possible to more reliably suppress a change in the position of the first contact point 33 in the first direction Z when the first contact point 33 contacts the contact object.

The socket 1 includes the first probe pin 10 and the second probe pin 10 spaced apart from the first probe pin 10 in the second direction X. The first contact point 33 of the first probe pin 10 is located at an end farther from the second probe pin 10 among both ends of the second elastic portion 31 in the second direction X. The first contact point 33 of the second probe pin 10 is located at an end farther from the first probe pin 10 among both ends of the second elastic portion 31 in the second direction X. With such a configuration, it is possible to realize the socket 1 contactable from the second direction X intersecting the first direction Z in which the first elastic portion 20 is elastically deformed.

The probe pin 10 can be configured as follows.

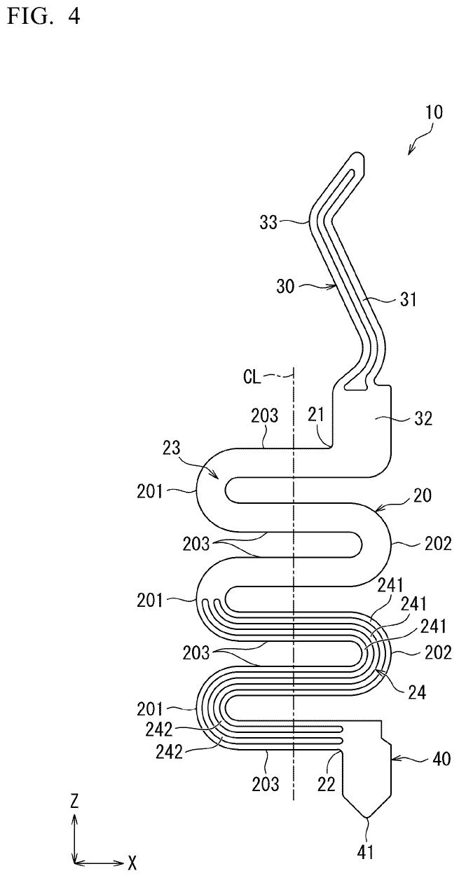

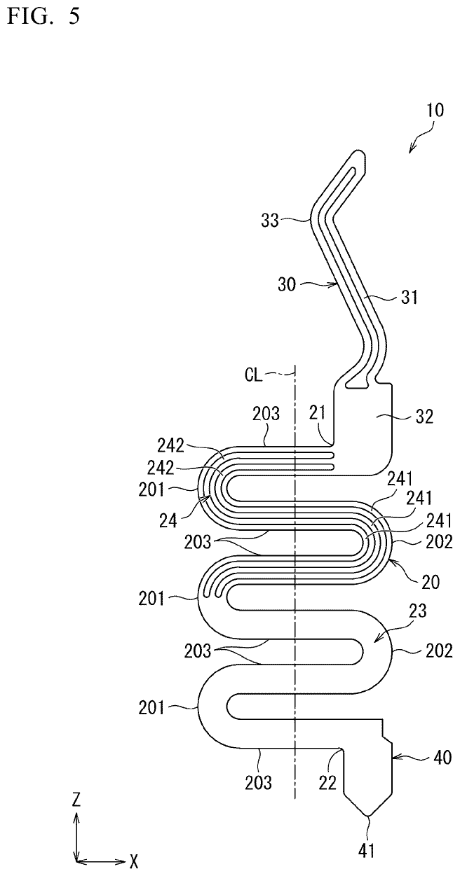

The first support portion 25, the second support portion 26, the first extension portion 27, and the second extension portion 28 may be omitted. FIGS. 4 and 5 illustrate an example of the probe pin 10 not including the first support portion 25, the second support portion 26, the first extension portion 27, and the second extension portion 28.

In the probe pin 10 of FIG. 4, the first elastic portion 20 includes three first curved portions 201 and two second curved portions 202. The portion constituting the second end 22 of the connecting portion 203 located closest to the second contact portion 40 constitutes the second portion 24.

The probe pin 10 of FIG. 5 differs from the probe pin 10 of FIG. 4 in the positions of the first portion 23 and the second portion 24. In the probe pin 10 of FIG. 5, the second portion 24 is located near the first contact portion 30, and the first portion 23 is located near the second contact portion 40.

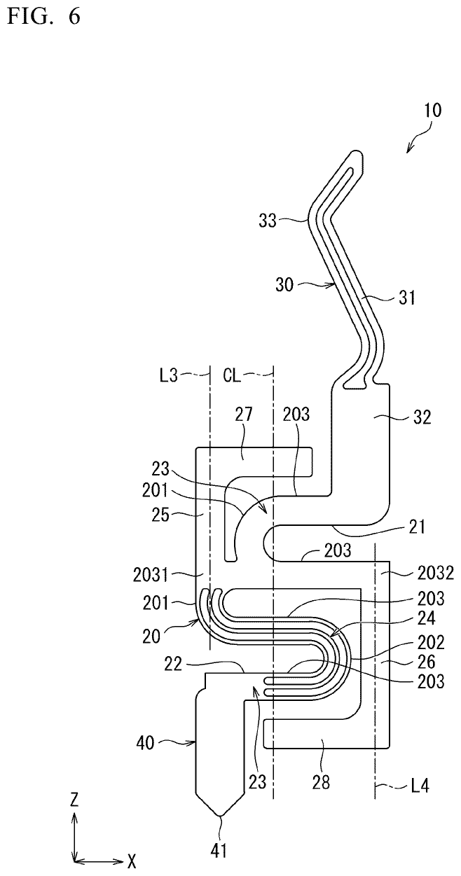

The first support portion 25 and the second support portion 26 may not be located on the same imaginary straight line L2. FIG. 6 illustrates an example of the probe pin 10 in which the first support portion 25 and the second support portion 26 are located on different virtual straight lines.

In the probe pin 10 of FIG. 6, the first contact portion 30 and the second contact portion 40 are located in different regions with respect to the center line CL. In the first elastic portion 20, the first portion 23 includes one first curved portion 201 and two connecting portions 203, and the second portion 24 includes one first curved portion 201, one second curved portion 202, and two connecting portions 203. The first curved portion 201 of the first portion 23 is located closer to the center line CL in the second direction X than the first curved portion 201 of the second portion 24. A virtual straight line passing through a middle of the first curved portion 201 and the second curved portion 202 of the second portion 24 and extending in the first direction Z is defined as a center line CL. The first support portion 25 and the second support portion 26 are connected from the connecting portion 203 (hereinafter, it is referred to as an intermediate connecting portion 203) closer to the second portion 24 among the two connecting portions 203 of the first portion 23. In the second direction X, the intermediate connecting portion 203 extends from a third end 2031 farther away from the center line CL than the first curved portion 201 of the first portion 23 through the center line CL to a fourth end 2032 farther away from the center line than the second curved portion 202 of the second portion 24. The third end 2031 is in the same region as the second contact portion 40 with respect to the center line CL, and the fourth end 2032 is in the same region as the first contact portion 30 with respect to the center line CL. The first support portion 25 extends from the third end 2031 of the intermediate connecting portion 203 along an imaginary straight line L3 substantially parallel to the center line CL. The second support portion 26 extends from the fourth end 2032 of the intermediate connecting portion 203 along an imaginary straight line L4 substantially parallel to the center line CL. The first curved portion 201 of the second portion 24 is connected to a part of the third end 2031 of the intermediate connecting portion 203 on the opposite side in the first direction Z of the portion to which the first support portion 25 is connected.

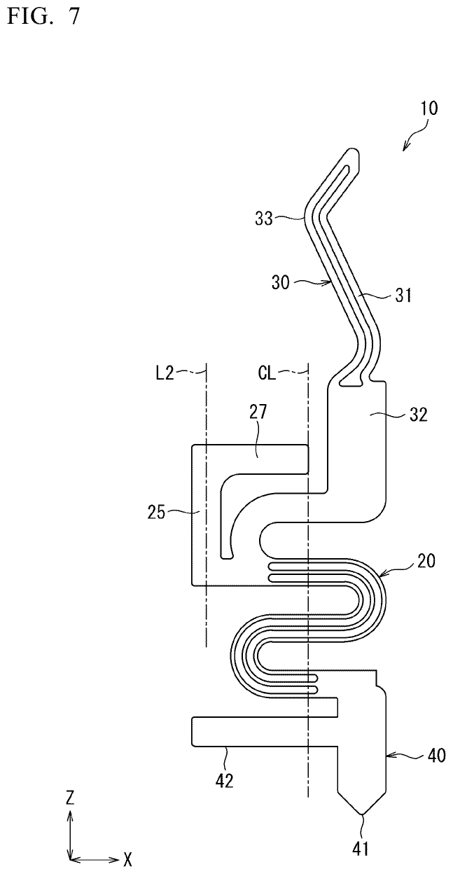

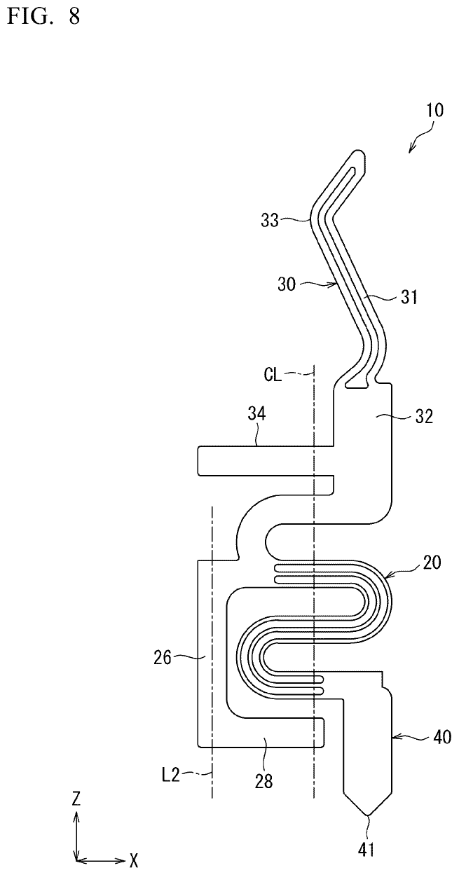

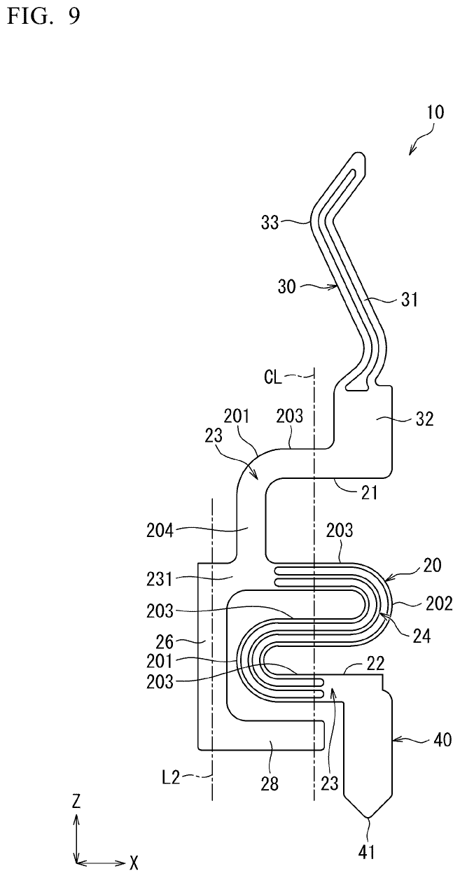

One of the first support portion 25 and the second support portion 26 may be omitted. FIG. 7 illustrates an example of a probe pin 10 in which the second support portion 26 and the second extension portion 28 are omitted, and FIGS. 8 and 9 illustrate an example of a probe pin 10 in which the first support portion 25 and the first extension portion 27 are omitted.

The probe pin 10 of FIG. 7 includes a third support portion 42 extending from the second contact portion 40 through the center line CL to the imaginary straight line L2 along the second direction X. The third support portion 42 is in contact with the member 53 in a state where the probe pin 10 is accommodated in the accommodating portion 501 of the core portion 5.

The probe pin 10 of FIG. 8 includes a fourth support portion 34 extending from the plate-like portion 32 of the first contact portion 30 through the center line CL to the imaginary straight line L2 along the second direction X. The fourth support portion 34 is in contact with the member 51 in a state where the probe pin 10 is accommodated in the accommodation portion 501 of the core portion 5.

The probe pin 10 of FIG. 9 includes a second connecting portion 204 in which the first portion 23 of the first elastic portion 20 extends from the auxiliary portion 231 in the first direction Z and in a direction approaching the first contact portion 30. The first curved portion 201 is connected to an end farther from the auxiliary portion 231 among both ends of the connecting portion 204 in the first direction Z.

Dimensions in the width direction of the elastic piece 241 of the second portion 24 may be all the same or different. Similarly, dimensions in the width direction of the elastic pieces 311 of the second elastic portion 31 may be all the same or different.

The elastic piece 241 and the gap 242 of the second portion 24 may or may not have a constant dimension in the width direction in the direction in which the second portion 24 extends. Similarly, the elastic piece 311 and the gap 312 of the second elastic portion 31 may or may not have a constant dimension in the width direction in the direction in which the second elastic portion 31 extends.

The first elastic portion 20 is not limited to the case of including the first portion 23 and the second portion 24. For example, the first elastic portion 20 may include only the first portion 23 or only the second portion 24 or may include a portion having a configuration different from that of the first portion 23 and the second portion 24.

The configuration of the first contact point 33 and the second contact point 41 including the shapes and dimensions may be selectively set according to a design or the like of the probe pin 10.

Various aspects of the present disclosure are described below with reference numerals.

A probe pin 10 according to a first aspect of the present disclosure includes:
a first elastic portion 20 configured to be elastically deformed in a first direction;
a first contact portion 30 including a second elastic portion 31 configured to be elastically deformed in a second direction intersecting the first direction, the first contact portion 30 being connected to a first end of the first elastic portion 20 in the first direction; and
a second contact portion 40 connected to a second end of the first elastic portion 20 in the first direction, the second end being located on an opposite side of the first end, wherein
the first contact portion 30 includes a first contact point 33 located at a position of the second elastic portion 31 that the first contact point 33 is superposed on the first elastic portion 20 when viewed along the first direction, the first contact point 33 being configured to be in contact along the second direction, and
the second contact portion 40 includes a second contact point 41 configured to be in contact along the first direction.

A probe pin 10 of a second aspect of the present disclosure is the probe pin according to the first aspect, wherein
the first elastic portion 20 includes:
   a first portion 23 configured by a single member; and
   a second portion 24 configured by a plurality of members.

A probe pin 10 of a third aspect of the present disclosure is the probe pin according to the second aspect, wherein
the first elastic portion 20 includes a first support portion 25 extending from the first portion 23 in the first direction and in a direction approaching the first contact portion 30.

A probe pin 10 of a fourth aspect of the present disclosure is the probe pin according to the second or third aspect, wherein
the first elastic portion 20 includes a second support portion 26 extending from the first portion 23 in the first direction and in a direction approaching the second contact portion 40.

A socket 1 according to a fifth aspect of the present disclosure includes:
the probe pin 10 according to any one of the first to fourth aspects; and
a housing 2 including an accommodating portion 501 that accommodates the probe pin 10, characterized in that
the first contact point 33 is located outside the accommodating portion 501.

A socket 1 of a sixth aspect of the present disclosure is the socket according to the fifth aspect, wherein
the first elastic portion 20 includes:
   a first portion 23 configured by a single member; and
   a second portion 24 configured by a plurality of members,
the first elastic portion 20 includes:
   a first support portion 25 extending from the first portion 23 in the first direction and in a direction approaching the first contact portion 30; and
   a first extension portion 27 extending in the second direction from an end closer to the first contact portion 30 of the first support portion 25 in the first direction, the first extension portion 27 being in contact with an inner surface of the housing 2 constituting the accommodating portion 501, and
a part of the first extension portion 27 is superposed on the first elastic portion 20 when viewed along the first direction.

A socket 1 of a seventh aspect of the present disclosure is the socket according to the fifth or sixth aspect, wherein
the first elastic portion 20 includes:
a second support portion 26 extending from the first portion 23 in the first direction and in a direction approaching the second contact portion 40; and
a second extension portion 28 extending in the second direction from an end closer to the second contact portion 40 of second support portion 26 in the first direction, the second extension portion 28 being in contact with an inner surface of the housing 2 facing in the first direction an inner surface of the housing 2 in contact with the first extension portion 27 among inner surfaces of the housing 2 constituting the accommodating portion 501, and
a part of the second extension portion 28 is superposed on the first elastic portion 20 when viewed along the first direction.

A socket 1 of an eighth aspect of the present disclosure is the socket according to any one of the fifth to seventh aspects, wherein,
the probe pin 10 includes:
   a first probe pin 10; and
   a second probe pin 10 located at an interval in the second direction with respect to the first probe pin 10,
the first contact point 33 of the first probe pin 10 is located at an end farther from the second probe pin 10 of the second elastic portion 31 in the second direction, and
the first contact point 33 of the second probe pin 10 is located at an end farther from the first probe pin 10 the second elastic portion 31 in the second direction.

The embodiment(s) and modification(s) of the present disclosure can be a combination of the embodiments, a combination of the modifications, or a combination of the embodiment(s) and the modification(s). It is also possible to combine features included in the embodiment(s) and modification(s) of the present disclosure.

The disclosure of the present disclosure should change in details of the configuration, and changes in combination and order of elements in each embodiment can be realized without departing from the scope and spirit of the claimed present disclosure.

### INDUSTRIAL APPLICABILITY

The probe pin and the socket of the present disclosure can be used for, for example, an electronic control unit (ECU) and an inspection related to the ECU.

### REFERENCE SIGNS LIST

1 socket
2 housing
3 main body portion
4 connecting portion
401 recess
402 opening
5 core portion
501 accommodating portion
10 probe pin
20 first elastic portion
201 first curved portion
202 second curved portion
203, 204 connecting portion
2031 third end
2032 fourth end
21 first end
22 second end
23 first portion
231 auxiliary portion
24 second portion
241 elastic piece
242 gap
25 first support portion
26 second support portion
27 first extension portion
28 second extension portion
30 first contact portion
31 second elastic portion
31 first curved portion
311 elastic piece
312 gap
313, 315 curved portion
314, 316 linear portion
32 plate-like portion
33 first contact point
34 fourth support portion
40 second contact portion
41 second contact point
42 third support portion
51, 52, 53 member
531 opening

1. A probe pin, comprising:
a first elastic portion configured to be elastically deformed in a first direction;
a first contact portion including a second elastic portion configured to be elastically deformed in a second direction intersecting the first direction, the first contact portion being connected to a first end of the first elastic portion in the first direction; and
a second contact portion connected to a second end of the first elastic portion in the first direction, the second end being located on an opposite side of the first end, wherein
the first contact portion includes a first contact point located at a position of the second elastic portion that the first contact point is superposed on the first elastic portion when viewed along the first direction, the first contact point being configured to be in contact along the second direction, and
the second contact portion includes a second contact point configured to be in contact along the first direction.

2. The probe pin according to claim 1, wherein
the first elastic portion includes:
a first portion configured by a single member; and
a second portion configured by a plurality of members.

3. The probe pin according to claims 2, wherein
the first elastic portion includes a first support portion extending from the first portion in the first direction and in a direction approaching the first contact portion.

4. The probe pin according to claim 2, wherein
the first elastic portion includes a second support portion extending from the first portion in the first direction and in a direction approaching the second contact portion.

5. A socket, comprising:
the probe pin according to claim 1; and
a housing including an accommodating portion that accommodates the probe pin, wherein
the first contact point is located outside the accommodating portion.

6. The socket according to claim 5, wherein
the first elastic portion includes:
a first portion configured by a single member; and
a second portion configured by a plurality of members,
a first support portion extending from the first portion in the first direction and in a direction approaching the first contact portion; and
a first extension portion extending in the second direction from an end closer to the first contact portion of the first support portion in the first direction, the first extension portion being in contact with an inner surface of the housing constituting the accommodating portion, and
a part of the first extension portion is superposed on the first elastic portion when viewed along the first direction.

7. The socket according to claim 5, wherein
the first elastic portion includes:
a second support portion extending from the first portion in the first direction and in a direction approaching the second contact portion; and
a second extension portion extending in the second direction from an end closer to the second contact portion of the second extension portion in the first direction, the second extension portion being in contact with an inner surface of the housing facing in the first direction an inner surface of the housing in contact with the first extension portion among inner surfaces of the housing constituting the accommodating portion, and
a part of the second extension portion is superposed on the first elastic portion when viewed along the first direction.

8. The socket according to claim 5, wherein
the probe pin includes:
a first probe pin; and
a second probe pin located at an interval in the second direction with respect to the first probe pin,
the first contact point of the first probe pin is located at an end farther from the second probe pin of the second elastic portion in the second direction, and
the first contact point of the second probe pin is located at an end farther from the first probe pin of the second elastic portion in the second direction.

9. A socket, comprising:
the probe pin according to claim 2; and
a housing including an accommodating portion that accommodates the probe pin, wherein
the first contact point is located outside the accommodating portion.

10. A socket, comprising:
the probe pin according to claim 3; and
a housing including an accommodating portion that accommodates the probe pin, wherein
the first contact point is located outside the accommodating portion.

11. A socket, comprising:
the probe pin according to claim 4; and
a housing including an accommodating portion that accommodates the probe pin, wherein
the first contact point is located outside the accommodating portion.
